(19) United States
(12) Patent Application Publication
(10) Pub. No.: US 2022/0377855 A1
(43) Pub. Date: Nov. 24, 2022

(54) OPTICAL ELEMENT WITH HEATER LAYER

(71) Applicant: LightPath Technologies, Inc., Orlando, FL (US)

(72) Inventor: Shmuel Rubin, Winter Park, FL (US)

(21) Appl. No.: 17/664,186

(22) Filed: May 19, 2022

Related U.S. Application Data
(60) Provisional application No. 63/202,002, filed on May 21, 2021.
(60) Provisional application No. 63/270,466, filed on Oct. 21, 2021.

(51) Int. Cl. H05B 3/86; G02B 1/04; H01L 23/34; C03C 3/32

(52) U.S. Cl. CPC H05B 3/86; G02B 1/041; H01L 23/345; C03C 3/321; H04N 5/22521

(57) ABSTRACT

Methods and systems for providing de-icing and/or de-fogging of an optical element include providing a resistive layer on an optically transparent material. In one embodiment, an optical system includes an optical device having a moldable optical material having a first surface, a resistive transparent material deposited in a layer on the first surface, and a conductive pad in electrical contact with the resistive transparent material. A method can include providing a moldable optical material having a first surface, a resistive transparent material deposited in a layer on the first surface, and a conductive pad in electrical contact with the resistive transparent material, and providing electrical energy to the conductive pad to heat the resistive transparent material.

### CROSS-REFERENCE TO RELATED APPLICATION(S)

The present application claims the benefit of priority to U.S. Provisional Patent Application No. 63/202,002, filed May 21, 2021, and to U.S. Provisional Patent Application No. 63/270,466, filed Oct. 21, 2021, which are incorporated herein by reference in their entireties. Any and all applications for which a foreign or domestic priority claim is identified in the Application Data Sheet as filed with the present application are hereby incorporated by reference as well as under 37 C.F.R. § 1.57.

### BACKGROUND OF THE INVENTION

### Field

The present disclosure relates to fabrication of a moldable optical element having a transparent heat resistive element.

### Description

Optical elements such as windows and lenses may be used in harsh environments where moisture, temperature (e.g., heat/cold), humidity, and so forth can result in the formation of precipitation or condensation on surfaces. While various chemical treatments may be used to mitigate the formation of ice or other residues on the surfaces of an optical element, these treatments may impact the optical quality of the lens. In some cases, it may not be feasible to apply such treatments due to accessibility problems (e.g., location of a lens or optical element within a larger system).

### SUMMARY

Systems and method for providing heating, for example, for de-icing and/or de-fogging, of an optical element such as a lens are disclosed herein. Some such systems and methods include providing a resistive layer on an optically transparent material. The optically transparent material may comprise, for example, moldable glass in some implementations. The resistive layer may comprise semiconductor in some cases. A wide range of designs are possible.

In various embodiments described herein, an optical system comprises: an optical device comprising a moldable optical material having a first surface; a resistive transparent material deposited in a layer on the first surface; and at least one conductive pad in electrical contact with the resistive transparent material. In some embodiments, an optical system comprises an infrared camera, and the infrared camera comprises the optical device. In some embodiments, the resistive transparent material comprises semiconductor. In some embodiments, the resistive transparent material comprises Germanium. In some embodiments, the optical system further comprises a diamondlike carbon coating on the resistive transparent material, such that the resistive transparent material is between the moldable optical material and the diamondlike carbon coating. In some embodiments, the moldable optical material comprises glass. In some embodiments, the moldable optical material comprises chalcogenide glass. In some embodiments, the moldable optical material is amorphous. In some embodiments, the moldable optical material is not a semiconductor.

In some embodiments, an optical element comprises: an optical material that is transparent having at least a first surface; and a resistive transparent layer that is at least partially conductive deposited on the first surface such that electrical power can be applied to the resistive transparent layer to heat the optical material. In some embodiments, the optical element comprises a lens or optical window. In some embodiments, the resistive transparent layer that is at least partially conductive comprises semiconductor. In some embodiments, the resistive transparent layer that is at least partially conductive comprises Germanium. In some embodiments, the optical element further comprises a hard coat layer on the resistive transparent layer, such that the resistive transparent layer is between the optical material and the hard coat layer. In some embodiments, the hard coat layer comprises a diamondlike carbon coating. In some embodiments, the optical material comprises glass. In some embodiments, the optical material comprises moldable material. In some embodiments, the optical material comprises moldable glass. In some embodiments, the optical material comprises chalcogenide glass. In some embodiments, the optical material is amorphous. In some embodiments, the optical material is not a semiconductor. In some embodiments, the optical element further comprises at least one conductive pad in electrical contact with the resistive transparent layer. In some embodiments, the optical element further comprises a plurality of conductive pads in electrical contact with the resistive transparent layer. In some embodiments, the optical element further comprises a central optical region, the resistive transparent layer disposed on over the central optical region. In some embodiments, the optical element comprises a lens having optical power.

In some embodiments, an optical element comprises: a body being optically transparent having a front surface and rear surface; and a heater layer being optically transparent located on the front surface comprising at least partially resistive material.

In some embodiments, an optical element comprises: a body having a front surface and rear surface comprising moldable glass; and a heater layer being optically transparent located on the front surface comprising at least partially resistive material.

In some embodiments, an optical element comprises: a body with a front surface and rear surface comprising chalcogenides; and a heater layer being optically transparent located on the front surface comprising at least partially resistive material.

In some embodiments, an optical element comprises: a body being optically transmissive having a front and rear surface and comprising semiconductor located on the front surface, the body comprising different material than the semiconductor on the front surface.

In some embodiments, an optical element comprises: a body being optically transparent having a front surface and rear surface, at least one of the front surface and rear surface having optical power; and a heater layer being optically transparent located on the front surface comprising at least partially resistive material.

In some embodiments, an optical element comprises: a body having a front surface and rear surface comprising moldable glass, at least one of the front surface and rear surface having optical power; and a heater layer being optically transparent located on the front surface comprising at least partially resistive material.

In some embodiments, an optical element comprises: a body with a front surface and rear surface comprising chalcogenides, at least one of the front surface and rear surface having optical power; and a heater layer being optically transparent located on the front surface comprising at least partially resistive material.

In some embodiments, an optical element comprises: a body being optically transmissive having a front and rear surface, at least one of the front surface and rear surface having optical power; and a heater layer comprising semiconductor located on the front surface. In some embodiments, the optical element further comprising a contact that is at least partially conductive. In some embodiments, the optical element comprises a lens.

### BRIEF DESCRIPTION OF THE DRAWINGS

These and other features, aspects, and advantages of the disclosure are described with reference to drawings of certain embodiments, which are intended to illustrate, but not to limit, the present disclosure. It will be understood that the accompanying drawings, which are incorporated in and constitute a part of this specification, are for the purpose of illustrating concepts disclosed herein and may not be to scale.

FIG. 1 is a side view illustrating an optical element formed from a moldable material (for example, chalcogenides) and having a resistive semiconductor layer that can be inexpensively manufactured by molding.

### DETAILED DESCRIPTION OF CERTAIN INVENTIVE ASPECTS

Optical elements like windows and lenses that are exposed to less than ideal operating environments may have one or more surfaces that have precipitation or condensation formed thereon. For example, the surfaces may have ice or “fog” formed thereon based on environmental conditions relating to moisture, temperature (e.g., heat or cold), humidity, etc. A de-icing or anti-fog spray may be applied to help mitigate ice or fog, but they can be messy and adversely affect the imaging quality of the optical element. Also, the optical surface may not be accessible. Accordingly, it would be advantageous to have an optical element that is structured to have de-icing or de-fogging functionality that does not adversely affect the imaging quality of the optical element. This technology provides a way for moldable materials, such as chalcogenides, to be inexpensively processed by molding, while allowing resistive heating to be applied by applying a current to a semiconductor layer.

Described herein are various embodiments relating to an optical element (e.g., a lens or window) formed from a moldable material with a transparent layer of a different material applied to an optical surface for use in resistive heating of the optical element. As used in reference to the transparent layer or a transparent material, “transparent” can mean, for example, transparent for one or more visible and/or infrared wavelengths. In some embodiments, the moldable material may be amorphous or non-semiconductor and may comprise glass such as moldable glass. In some embodiments, the transparent layer may comprise a different material, for example a semiconductor material like Germanium (Ge). Embodiments of the invention may be applied to an optical element in any system where heating of an optical element is desired, for example, to provide de-icing and/or de-fogging. In some embodiments, the system may be an infrared camera, or any other type of camera or imaging system. In some embodiments, the system may be an optical device, for example, a telescope, binoculars, periscope, rangefinder, etc. In other examples, the system may be any type of optical system where optical elements in the system may experience exposure to water and/or freezing conditions, which can lead to ice or fog forming on a surface of an optical element.

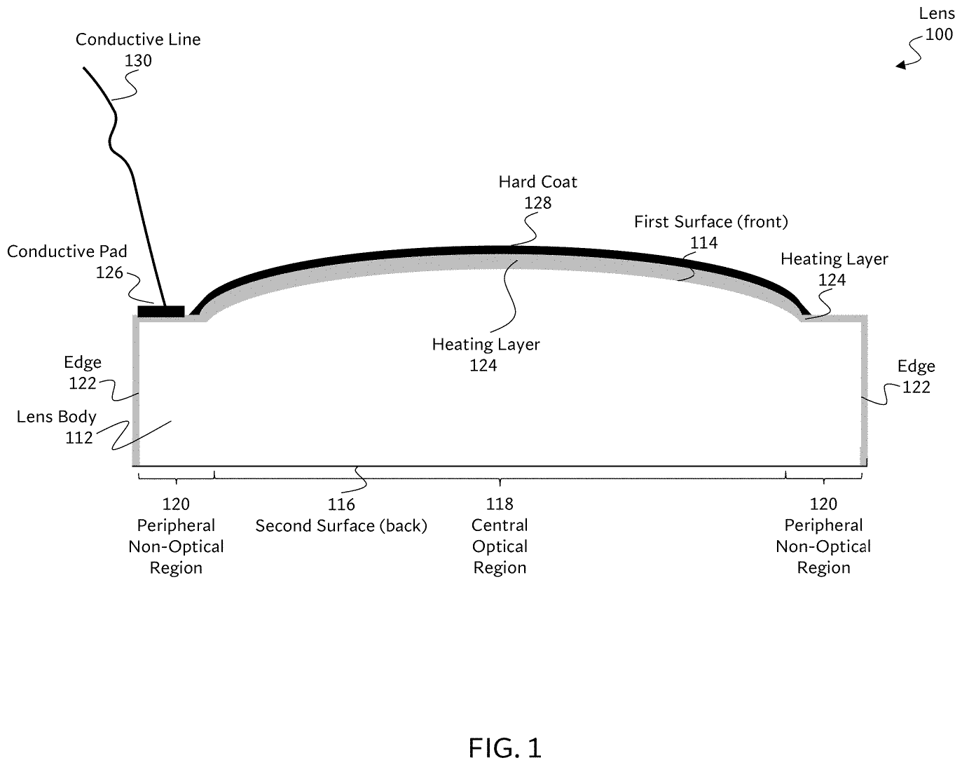

FIG. 1 is a side view illustrating an embodiment of the invention, where in this example the optical element (e.g., lens) is formed from a moldable material (for example, chalcogenides), having a semiconductor layer that can be formed on the optical element, for example, by deposition such as by physical vapor deposition (PVD). In various implementations, the semiconductor can have some resistance such that applying a voltage across electrical contact formed with the semiconductor may cause a current to pass therethrough and produce resistive heating. In this example, the optical element (e.g., lens) can be formed from a moldable material (e.g., chalcogenide) and include a layer of Ge (“Ge heating layer”) semiconductor deposited on an optical surface of the optical element. The optical element has a conductive pad formed or positioned thereon that is in contact with the Ge heating layer. The optical element has a diamondlike carbon (DLC) coating on the Ge heating layer, such that the Ge heating layer is between the DLC coating and the moldable material (e.g., lens material). The DLC coating helps the surface of the optical element (e.g., the lens surface) to withstand harsh environmental conditions. Via the conductive pad, a voltage can be applied such that the Ge heating layer operates as a resistive heating element that heats the optical surface of the optical element (e.g., lens) and prevents or minimizes fogging and icing of the optical element (e.g., lens).

In particular, FIG. 1 shows a cross-sectional view of an optical element 100 such as a lens. The optical element 100 need not be a lens, but can be a window or other optical element. The lens 100 shown in FIG. 1 has a body 112 having a first surface 114 and second surface 116 thereon. In various implementations, the first surface 114 may comprise the front or forward surface of the body 112 and the second surface 116 may comprise the back, rear or rearward surface of the body. The body 112 of the optical element 100 is optically transparent, comprising, for example, an optically transparent material. As discussed above, the body 112 and optical material may be optically transparent to visible and/or infrared light.

In some implementations, the body 112 comprises glass such as moldable glass. In some implementations, the body 112 comprises chalcogenide glass or one or more chalcogenides. For example, the glass may comprise BD6 glass available from LightPath Technologies, Inc., Orlando, Fla.

In some implementations, the body 112 comprises rigid material that is optically transparent to light such as visible and/or infrared wavelengths. As referenced above, the optical element 100 shown in FIG. 1 comprises a lens having optical power. Such optical power can be provided, for example, by the first and/or second surfaces 114, 116. For example, either or both the first and/or second optical surfaces 114, 116 may be curved or shaped to provide optical power. In the implementation shown in FIG. 1, for example, the first surface is curved and, in particular, has a convex curvature. The first surface need not be convex, however, but can be concave or flat in other implementations. The second surface 116 of the optical element 100 shown in FIG. 1 is flat. The second surface need not have a flat shape though. In some implementations, for example, the second surface 116 can be curved and have a concave or a convex curvature. Either or both the first or second surfaces 114, 116, if curved, can have spherical or aspherical curvature.

The optical element 112 in FIG. 1 includes a central optical region 118 and peripheral non-optical region 120. Similarly, the first and second surfaces 114, 116 include a central optical region 118 and peripheral non-optical region 120. In the example shown in FIG. 1, the central region 118 of the optical element 100, and namely of the first surface 114, includes optical power. In contrast, the peripheral region 120 of the lens shown in FIG. 1, does not have optical power. Accordingly, the central region 118 of the optical element 100 may have optical characteristics that can be used to manipulate light in an optical system such as an optical lens like a camera lens. Likewise, in various implementations the central optical portion 118 of the first and/or second optical surfaces 114, 116 comprises optical surfaces that are sufficiently smooth to reduce optical scatter. These optical surfaces may also be configured, e.g., curved, to provide optical power or other optical effect such as aberration reduction, etc. In contrast, the peripheral non-optical portion 120 of the optical element 100 may provide no contribution to the manipulation of light in an optical system provided by the central optical region 118. Although FIG. 1 shows the peripheral non-optical region 120 portion of the body 112 of the lens 100 as flat, in other implementations, the peripheral non-optical region of the body of the lens need not be flat and/or may be transparent. In some implementation, however, the optical beam does not pass through the peripheral non-optical region 120, possibly as a result of other components (such as opaque components) that limit the spatial extent of the beam. In various implementations, the peripheral non-optical region 120 may be employed for other uses such as to mount the lens. Accordingly, in certain implementations, the lateral dimension of the central optical region 118 corresponds to the clear aperture of the lens 100. For some designs, this central optical region 118 may correspond, for example, to 80-99%, 82%-98%, 83%-97% or 85-95% (e.g., 90%) of the first surface 114 of the optical element or lens 100 and/or 80-99%, 82%-98%, 83%-97% or 85-95% (e.g., 90%) of the second surface 116 of the optical element or lens or any range formed by any of these values, although values outside these ranges are also possible. The body 112 of optical element 100 also has edges or a perimeter 122. In the example shown, the edges 122 are included in the peripheral non-optical region 120.

The optical element or lens 100 of FIG. 1 also includes a heater layer 124 formed on a surface thereof, in this case, the first surface 114. In various implementations, the heater layer 124 is disposed on the front surface of an optical system that includes the optical element or lens 100. This front surface may be exposed to ambient environment and may therefore have moisture formed thereon from, e.g., precipitation and/or condensation. The heater layer 124 may comprise one or more resistive layers that possess sufficient resistance such that when a voltage is applied across the resistive layer current flows therethrough causing heating of the heater layer and the optical element or lens 100 or at least the surface (e.g., first surface) 114, 116 thereof on which the heater layer is deposited. In various implementations, the heating layer 124 may be included on the first surface (e.g., first major surfaces) 114 and not on the second surface (e.g., second major surface) 116. In some implementations, heater layers 124 are included on both the first and second surfaces (e.g., first and second major surfaces) 114, 116. Heater layers 124 may, for example, be included on both the front and rear sides of the optical element 100. In some implementations, the heating layer 124 is included on the edges 122 as well although in various implementations, the heating layer is not included on the edges 112. In many implementations, the heating layer 124 is disposed on the central optical region 118 of the lens or optical element 100. Accordingly, in various implementations the heating layer 124 is optically transmissive and in particular, transparent to infrared and/or visible light. In some implementations, the heating layer 124 is on the peripheral non-optical region 120 as well although in various implementations, the heater layer is not on the non-optical region. Although the heater layer 124 is shown disposed directly on the body 112 of the optical element 100, in various implementations one or more layers of material may be disposed between the heater layer and body of the lens or optical element.

As discussed above, the heater layer 124 may comprise at least one at least partially resistive material. In some implementations, the heater layer 124 comprises at least one semiconductor material. In some implementations, for example, the heater layer 124 comprises Germanium or possibly Silicon, although other semiconductor materials may be employed. The semiconductor layer may be doped or undoped depending on the design and may be lightly or heavily doped to provide a suitable level of conductivity and/or resistance. In some implementations, however, the heater layer 124 need not comprise a semiconductor. In various implementations, the heater layer 124 is sufficiently thin to be transparent.

In various implementations, the optical element 100 further comprises a contact or contact pad 126. In various implementations, at least two contact pads 126 are included and employed to provide electrical power to the heater layer 124 although only one may be visible in FIG. 1. The contact pad 126 may comprise at least partially conductive material such as metal. In some implementations, for example, the contact pad 126 comprises copper. However, the contact pad 126 can comprise any conductive material. The heater layer 24 is in electrical contact with the contact pad 126. In the example shown in FIG. 1, the contact pad is disposed on the heater layer 124. In various implementations, the contact pad 126 forms a contact that allows electricity to conduct into the heater layer 124, which may comprise semiconductor as discussed above. In various implementations, one or more conductive lines 130 such as wires or leads may be connected to the contact pad 126 providing an electrical path thereto. Accordingly, in various implementations a voltage may be applied to the conductive pad 126 possibly through the conductive line 130 and current may flow through the conductive line, the conductive pad and the heater layer 124, which may comprise resistive/partially conductive material.

The lens implementation of FIG. 1 also comprises an optional front protective layer 128 such as a hard coat. In some designs, this hard coat 128 may be applied to the heater layer 124 or portions thereof such as portions in the central optical region 118. The hard coat 128 may also be applied to the body 112 or portions thereof such as portions of the central optical region 118 and/or peripheral non-optical region 120 not covered by the heater layer 124 in some cases. In some implementations, one or more optical layer such as one or more special performance layers may be disposed on the opposite side of the lens or optical element 10 as the side on which the heater layer 124 is located. In the implementation shown, the optional front protective layer 128 at least partially covers the heater layer 124. The optical element 100, however, need not have a front protective layer 128. In cases where a protective front layer 128 is present though, the protective front layer may be used to protect the heater layer 24 from corrosion or physical damage and/or to protect the body 112 of the lens or optical element 100 from damage such as from scratching. Accordingly, this protective layer 128 may be the outermost layer on the optical element 100 (e.g., on the front of the lens),In various implementations, the optional protective front layer 128 is optically transparent (e.g., to infrared and/or visible light) at least in areas disposed over the central optical region 118. Accordingly, this protective layer or hard coat 128 may comprise, for example, transparent material that is transparent to visible and/or infrared light. As described above, in some implementations, this hard coat 128 may comprise diamondlike carbon. In some implementations, the front layer 128 comprises other material transparent to visible and/or infrared wavelengths.

In operation, the contact pad 126 is connected to an electrical power source such as a current source (not shown) via the conductive line 130. Electrical current then passes from the electrical source through the contact pad 126 and the heater layer 124. Electrical current flowing through a resistive material produces heat. Likewise, the electrical current flowing through the heater layer 124 produces resistive heating that heats at least the front surface 114 of the body 112 of the optical element or lens 100 and possibly heats the body itself. In some implementations, the amount of heat produced can be controlled by controlling the electrical power applied by the electrical source and/or control circuit (not shown). In the implementation presented by FIG. 1, the heat produced by the current passing through the heater layer 124 can potentially raise the temperature of the optical element or lens 100 or at least the first surface 114 sufficiently to reduce or prevent condensation from forming or possibly facilitate increased evaporation of the fluid formed thereon. Such action may counter the obscuring, distorting, or light scattering effects produced by moisture such as condensation.

In various implementations, the lens body 112 may be formed by molding although other methods may be used. The heater layer 124 may be deposited on the lens body by thin film deposition processes or other methods. Similarly, the contact pads 126 and hard coat 128 may be formed by thin film deposition processes. Other methods may be employed.

In various implementations, the heating layer 124 comprises a thin film or is at least thin compared to the body 112 or the element or lens 100. In various implementations, the thickness (e.g., center thickness, edge thickness, average thickness, etc.) of the body 112 may vary depending on the type of optical element. In some cases, however, the body 112 is at least 10 times, 20 times, 50 times, 100 times, 200 times, 500 times, 1000 times, 2000 times, 5000 times, 10000 times as thick as the resistive heating layer 124 or any range formed by any of these values. Thicknesses outside these ranges are also possible.

In various implementations, the heating layer 124 comprises more than just one conductive line 130.

In various implementations, the heating layer 124 comprises an area at least 3 mm×3 mm, 5 mm×5 mm, 10 mm×10 mm, 50 mm×50 mm, 100 mm×100 mm, or 200 mm×200 mm, or any range between any of these values or values outside these ranges. Similarly, the heating layer 124 may comprise an area of more than πr², the area of a circular region, where r is the radius of the circular region and r can be from 1 mm, 2 mm, 3 mm, 5 mm, 10 mm, 15 mm, 20 mm, 50 mm, 100 mm, 120 mm, or any range between any of these values or values outside these ranges. This radius, r, may correspond to the radius of the first and/or second surface 114, 116 of the lens or optical element 100 and/or the radius of the clear aperture or the central optical region 118 of the lens or optical element. In various implementations, the optical element 100 may comprise a lens having any shape optical surfaces 114, 116. For example, the optical element 10 may comprise a lens having a surface 114, 116, with a radius of curvature from 5 mm to plano. Other optical elements are possible. In various implementations, the heating layer 124 may cover at least 50%, 70%, 80%, 90%, 95%, 99.5%, or 100% of the area of the first and/or second surface 114, 116 of the body of the optical element or lens 100 and/or of the central optical region 118, or any range between any of these values or possibly outside these ranges.

In various implementations, the heating layer 124 may have a circular footprint or cover an area having a circular footprint or area. Alternatively, in various implementations, the heating layer 24 may have a square footprint or cover an area having a square footprint or area. In various implementations, the heating layer 124 may have a rectangular footprint or cover an area having a rectangular footprint or area. The aspect ratio (the ratio of the length to the width) of the rectangular footprint or area may be between 5:1 to 1:1 or 4:1 to 1:1 or 3:1 to 1:1 or 2:1 to 1:1 or any range between any of these values or values outside these ranges. Other shapes are possible as well.

### EXAMPLES

Some additional nonlimiting examples of embodiments discussed above are provided below. These should not be read as limiting the breadth of the disclosure in any way.

Example 1: An optical system, comprising:
an optical device comprising
   a moldable optical material having a first surface;
   a resistive transparent material deposited in a layer on the first surface; and
   at least one conductive pad in electrical contact with the resistive transparent material.

Example 2: The optical system of Example 1, comprising an infrared camera, the infrared camera comprising the optical device.

Example 3: The optical system of any of the examples above, wherein the resistive transparent material comprises semiconductor.

Example 4: The optical system of any of the examples above, wherein the resistive transparent material comprises Germanium.

Example 5: The optical system of any of the examples above, further comprising a diamondlike carbon coating on the resistive transparent material, such that the resistive transparent material is between the moldable optical material and the diamondlike carbon coating.

Example 6: The optical system of any of the examples above, wherein the moldable optical material comprises glass.

Example 7: The optical system of Example 6, wherein the moldable optical material comprises chalcogenide glass.

Example 8: The optical system of any of the examples above, wherein the moldable optical material is amorphous.

Example 9: The optical system of Example 1, wherein the moldable optical material is not a semiconductor.

Example 10: An optical element comprising:
an optical material that is transparent having at least a first surface; and
a resistive transparent layer that is at least partially conductive deposited on the first surface such that electrical power can be applied to the resistive transparent layer to heat the optical material.

Example 11: The optical element of Example 10, wherein said optical element comprises a lens or optical window.

Example 12: The optical element of any of the examples above, wherein the resistive transparent layer that is at least partially conductive comprises semiconductor.

Example 13: The optical element of any of the examples above, wherein the resistive transparent layer that is at least partially conductive comprises Germanium.

Example 14: The optical element of any of the examples above, further comprising a hard coat layer on the resistive transparent layer, such that the resistive transparent layer is between the optical material and the hard coat layer.

Example 15: The optical element of Example 4, wherein said hard coat layer comprises a diamondlike carbon coating.

Example 16: The optical element of any of the examples above, wherein the optical material comprises glass.

Example 17: The optical element of any of the examples above, wherein the optical material comprises moldable material.

Example 18: The optical element of any of the examples above, wherein the optical material comprises moldable glass.

Example 19: The optical element of any of the examples above, wherein the optical material comprises chalcogenide glass.

Example 20: The optical element of any of the examples above, wherein the optical material is amorphous.

Example 21: The optical element of any of the examples above, wherein the optical material is not a semiconductor.

Example 22: The optical element of any of the examples above, further comprising at least one conductive pad in electrical contact with the resistive transparent layer.

Example 23: The optical element of any of the examples above, further comprising a plurality of conductive pads in electrical contact with the resistive transparent layer.

Example 24: The optical element of any of the examples above, further comprising a central optical region, said resistive transparent layer disposed on over said central optical region.

Example 25: The optical element of any of the examples above, wherein said optical element comprises a lens having optical power.

Example 26: An optical element comprising:
a body being optically transparent having a front surface and rear surface; and
a heater layer being optically transparent located on said front surface comprising at least partially resistive material.

Example 27: An optical element comprising:
a body having a front surface and rear surface comprising moldable glass; and
a heater layer being optically transparent located on said front surface comprising at least partially resistive material.

Example 28: An optical element comprising:
a body with a front surface and rear surface comprising chalcogenides; and
a heater layer being optically transparent located on said front surface comprising at least partially resistive material.

Example 29: An optical element comprising:
a body being optically transmissive having a front and rear surface; and;
comprising semiconductor located on said front surface, said body comprising different material than said semiconductor on said front surface.

Example 30: A lens comprising:
a body being optically transparent having a front surface and rear surface, at least one of said front surface and rear surface having optical power; and
a heater layer being optically transparent located on said front surface comprising at least partially resistive material.

Example 31: An optical element comprising:
a body having a front surface and rear surface comprising moldable glass, at least one of said front surface and rear surface having optical power; and
a heater layer being optically transparent located on said front surface comprising at least partially resistive material.

Example 32: An optical element comprising:
a body with a front surface and rear surface comprising chalcogenides, at least one of said front surface and rear surface having optical power; and
a heater layer being optically transparent located on said front surface comprising at least partially resistive material.

Example 33: An optical element comprising:
a body being optically transmissive having a front and rear surface, at least one of said front surface and rear surface having optical power; and
a heater layer comprising semiconductor located on said front surface.

Example 34: The optical element of any of the claims above, further comprising a contact that is at least partially conductive.

Example 35: The optical element of any of the claims above, wherein the optical element comprises a lens.

### Additional Embodiments

In the foregoing specification, the methods and systems have been described with reference to specific embodiments thereof. It will, however, be evident that various modifications and changes may be made thereto without departing from the broader spirit and scope of the disclosure. The specification and drawings are, accordingly, to be regarded in an illustrative rather than restrictive sense.

Indeed, it will be appreciated that the systems and methods of the disclosure each have several innovative aspects, no single one of which is solely responsible or required for the desirable attributes disclosed herein. The various features and processes described above may be used independently of one another, or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

Additionally, the various processes, blocks, states, steps, or functionalities may be combined, rearranged, added to, deleted from, modified, or otherwise changed from the illustrative examples provided herein. The methods and processes described herein are also not limited to any particular sequence, and the blocks, steps, or states relating thereto may be performed in other sequences that are appropriate, for example, in serial, in parallel, or in some other manner. Tasks or events may be added to or removed from the disclosed example embodiments. Moreover, the separation of various system components in the embodiments described herein is for illustrative purposes and should not be understood as requiring such separation in all embodiments.

It will be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Accordingly, the claims are not intended to be limited to the embodiments shown herein, but are to be accorded the widest scope consistent with this disclosure, the principles and the novel features disclosed herein.

What is claimed is:

1. An optical element comprising:
an optical material that is transparent having at least a first surface; and
a resistive transparent layer that is at least partially conductive deposited on the first surface such that electrical power can be applied to the resistive transparent layer to heat the optical material,
wherein said optical element comprises a lens having optical power.

2. The optical element of claim 1, wherein the resistive transparent layer that is at least partially conductive comprises semiconductor.

3. The optical element of claim 2, wherein the resistive transparent layer that is at least partially conductive comprises Germanium.

4. The optical element of claim 1, further comprising a hard coat layer on the resistive transparent layer, such that the resistive transparent layer is between the optical material and the hard coat layer.

5. The optical element of claim 4, wherein said hard coat layer comprises a diamondlike carbon coating.

6. The optical element of claim 1, wherein the optical material comprises glass.

7. The optical element of claim 6, wherein the optical material comprises moldable material.

8. The optical element of claim 6, wherein the optical material comprises moldable glass.

9. The optical element of claim 6, wherein the optical material comprises chalcogenide glass.

10. The optical element of claim 1, wherein the optical material is amorphous.

11. The optical element of claim 1, wherein the optical material is not a semiconductor.

12. The optical element of claim 1, further comprising at least one conductive pad in electrical contact with the resistive transparent layer.

13. The optical element of claim 1, further comprising a plurality of conductive pads in electrical contact with the resistive transparent layer.

14. The optical element of claim 1, further comprising a central optical region, said resistive transparent layer disposed on over said central optical region.
